(19) United States
(12) Patent Application Publication
(10) Pub. No.: US 2007/0063208 A1
(43) Pub. Date: Mar. 22, 2007

(54) Nanocrystal/photonic crystal composites

(76) Inventors: Victor I. Klimov, Los Alamos, NM (US); Garry R. Maskaly, Los Alamos, NM (US); Melissa Petruska, Brookfield, CT (US)

Correspondence Address: LOS ALAMOS NATIONAL SECURITY, LLC, LOS ALAMOS NATIONAL LABORATORY, PPO. BOX 1663, LC/IP, MS A187, LOS ALAMOS, NM, 87545, US

(21) Appl. No.: 11/388,409

(22) Filed: Mar. 24, 2006

Related U.S. Application Data
(60) Provisional application No. 60/665,105, filed on Mar. 25, 2005.

(51) Int. Cl. H01L 33/00

(52) U.S. Cl. 257/97

(57) ABSTRACT

The present invention is directed to composite photonic crystal materials of a photonic crystal structure having voids throughout, where the photonic crystal structure includes a colloidal nanocrystal-doped composite infiltrated within the voids, the colloidal nanocrystal-doped composite including a sol-gel or polymeric host/matrix material.

### RELATED CASES

This application claims the benefit of U.S. Provisional Patent Application Ser. No. 60/665,101 filed on Mar. 24, 2005, incorporated by reference herein.

### STATEMENT REGARDING FEDERAL RIGHTS

This invention was made with government support under Contract No. W-7405-ENG-36 awarded by the U.S. Department of Energy. The government has certain rights in the invention.

### FIELD OF THE INVENTION

The present invention relates to nanocrystal/photonic crystal composites and to processes of forming such nanocrystal/photonic crystal composites. Such nanocrystal/photonic crystal composites serve as active photonic crystals. Additionally, the present invention relates to reduction of lasing thresholds and enhanced tunability of laser materials by use of composite photonic crystal materials with a nanocrystal-containing host matrix material within the photonic crystal as a gain medium.

### BACKGROUND OF THE INVENTION

The use of opalescent materials as photonic crystals (PCs) has been widely studied. Photonic crystals have been used by scientists to control and manipulate the behavior of light. These dielectric structures are characterized by a periodic variation in their index of refraction, which gives rise to photonic bands that are similar to the electronic bands in crystalline solids. Like its electronic analogue, the optical photonic crystal exhibits a photonic bandgap or a region in which photons cannot propagate. Many optical properties of photonic crystal-based devices, such as their reflectivity, the density of optical states available within the structures, and the position of this photonic bandgap, can be tuned by controlling the structure of the device and its constituents.

Nanocrystal-doped sol-gels (SG/NC) have been previously described. Specifically, CdSe NC-titania nanocomposites have been prepared with NC volume loadings up to about 20 percent and a refractive index tunable to 2.1. An application of interest for PCs is as laser materials with a lower lasing threshold (reduced power needs) and enhanced tunability (broader application).

Interest in the possibility of compact, low-threshold or even thresholdless lasers has motivated investigations of the emission of active materials embedded in photonic crystal (PC) structures. The sharp decrease in the group velocity of light at the photonic band edge increases the interaction time of the light with the gain medium. Such gain enhancements have been observed in a variety of PC systems, including 1D, 2D, and 3D structures. While modification of the spontaneous emission of nanocrystals (NCs) has been shown in artificial opals, amplified spontaneous emission (ASE) or lasing from a colloidal NC/opal composite structure has not yet been demonstrated.

The present invention is further directed to a method of incorporating fluorescent semiconductor nanocrystals into PCs for lasing applications and to obtaining a reduced threshold for laser action.

### SUMMARY OF THE INVENTION

In accordance with the purposes of the present invention, as embodied and broadly described herein, the present invention provides a composite photonic crystal material including a photonic crystal structure having voids throughout, the photonic crystal structure including a colloidal nanocrystal-doped composite infiltrated within the voids, the colloidal nanocrystal-doped composite including a sol-gel or polymeric host/matrix material.

The present invention still further provides a process for preparing a composite photonic crystal material including filling a photonic crystal structure having voids throughout with a colloidal nanocrystal-doped composite precursor mixture for a period of time sufficient to form the composite photonic crystal material.

The present invention still further provides process of forming a one-dimensional composite photonic crystal material including forming alternating layers of (a) a photonic medium and (b) a colloidal nanocrystal-doped polymeric material upon a suitable substrate.

The present invention still further provides a one dimensional composite photonic crystal material including a substrate and alternating layers of (a) a photonic medium and (b) a colloidal nanocrystal-doped polymeric or sol-gel material thereon the substrate

### BRIEF DESCRIPTION OF THE DRAWINGS

FIG. 1(a) shows stop band positions as evidenced by dips in transmittance spectrum both before and after infiltration for the visible wavelength with a cadmium selenide (CdSe) sample. A shift of the band position is clearly evident (about 10%).

FIG. 1(b) shows stop band positions as evidenced by dips in transmittance spectrum both before and after infiltration for the infrared wavelength with a lead selenide (PbSe) sample. A shift of the band position is clearly evident (about 8%).

FIG. 2(a) shows the photoluminescent (PL) spectrum of a CdSe NC/sol-gel film (centered at 629 nm) with amplified spontaneous emission (ASE) at 647 nm with increasing pump power.

FIG. 2(b) shows the photoluminescent (PL) spectrum of the same CdSe SG/NC material infiltrated into an opal has a red-shifted center position and a blue-shifted ASE peak (both to 642 nm).

FIG. 2(c) shows schematically the shift of both the exciton (x) and biexiton (bx) peaks. The peaks shift to the same position on the edge of the photonic pseudogap.

FIG. 3(a) shows the photoluminescent (PL) spectrum maximum of another NC/sol-gel material (centered at 631 nm) with amplified spontaneous emission (ASE) at 649 nm. No significant change in ASE position was observed with increasing pump power (shown by dashed line).

FIG. 3(b) shows the photoluminescent (PL) spectrum maximum of the same NC/sol-gel material embedded in an opal (centered at 640 nm) with a shifting ASE maximum first developing at 646 nm and red-shifting with increasing pump power (shown by dashed line). The red-shifting may be due to nonlinearities in the refractive index of the NCs, which in turn shifts the pseudogap position and thereby the ASE position. Overlap is clear between the PL and the pseudogap position (see inset). The ASE threshold was reduced from that of the sol-gel film and the reduction in threshold occurred despite the near order of magnitude reduction in the NC volume fraction in the opaline sample, indicative of a strong photonic effect.

FIG. 4 shows a schematic drawing of a one-dimensional lasing device with alternating layer of a photonic medium and a nanocrystalline quantum dot (NQD) sol-gel medium on a substrate. Operation of this device is similar to a Fabry-Perot cavity in which feedback is accomplished by two parallel planes.

### DETAILED DESCRIPTION

The present invention is concerned with nanocrystal/photonic crystal composites. The basic photonic crystal structure can be from among one-dimensional structures, two-dimensional structures and three-dimensional structures. In one embodiment, nanocrystal/photonic crystal composite of the present invention can include colloidal nanocrystals and a polymeric or sol-gel host/matrix embedded within a photonic crystal structure. Such nanocrystal/photonic crystal composites serve as active photonic crystals, i.e., they exhibit the properties of the nanocrystals in addition to the properties of the photonic crystal.

As used herein, the term “nanocrystal” refers to particles less than about 150 Angstroms in the largest axis, and preferably from about 10 to about 150 Angstroms. Also, within a particularly selected colloidal nanocrystal, the colloidal nanocrystals are substantially monodisperse, i.e., the particles have substantially identical size and shape.

For simplicity, the term “photonic crystal” refers to a material with a periodic index of refraction, or a periodic array of small regions (e.g. voids) with a first dielectric constant, ε (e.g., ε approximately equal to 1 for voids) dispersed in a matrix with a second dielectric constant.

In one embodiment of the present invention, the composite photonic crystal material includes a titania sol-gel (SG)/CdSe NC composite infiltrated into a polystyrene artificial opal PC grown via vertical deposition. It has been demonstrated that this NC/SG/PC composite exhibits a decrease in threshold relative to the SG/NC materials despite the lower volume loading of NCs. This procedure can be extended to NC/PC composites tuned to near infrared wavelengths. The photonic crystal structure can be formed from other materials as well, such as, e.g., silica, alumina and titania.

Advantages of using such an SG/NC-based system can include environmental robustness by the SG/NC, high photoluminescense (PL) quantum yields from the SG/NC, and a large tunable index of refraction by the SG/NC material. Incorporation of a SG/NC material (or incorporation of a suitable polymeric matrix in place of the sol-gel matrix, e.g., an acrylate or methacrylate material) into the photonic crystal structure can enhance the performance of these materials with significant improvements in the NC gain (e.g., as much as an order of magnitude). The photonic crystal band gap enhancements of the SG/NC, either alone or coupled with other variations such as, e.g., use of quantum rods and core-shell structures, may allow such SG/NC/PC materials to function such that continuous wave lasers can generate amplified spontaneous emission. Other improvements in the photonic crystal structure may result in lasing without a separate external cavity as the photonic crystal itself may provide feedback. The robust nature of the SG/PC (or with another polymeric host/matrix material) can provide a long-lasting gain medium, while the ability to tailor NC emission (via changing the NC size and/or composition) and the photonic crystal bandgap (by changing the lattice parameter and indices of refraction) may provide the ability to produce lasers tunable across a wide spectral range. Ultimately, amplified spontaneous emission may be utilized as a bright light source for display technologies.

The stability of the composite photonic crystal materials of the present invention can allow fabrication of NC-based devices that demonstrate lasing. By merging photonic crystals (feedback element) with NCs (optical gain medium) into a single composite material, the opportunity exists to realize a highly efficient lasing structure using simple, wet chemical methods that obviate the need for more costly fabrication.

Infiltrating photonic crystals with NCs has been explored in the recent literature.

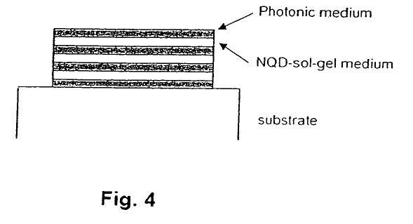

Despite these efforts, substantial evidence for ASE and lasing were not reported, and factors such as low NC loadings in the materials and poorly controlled NC surface properties likely contributed to the failure of these materials as active optical structures. In the approach of the present invention, the optical integrity of the NCs can be preserved by stabilizing them in, e.g., sol-gel or other polymeric matrices with high volume loadings and high photoluminescence quantum yields. Both of these factors are extremely important for observing ASE using these materials. In one embodiment, a device may consist of alternating layers of an active photonic crystal medium and a NC-sol-gel component upon a substrate (see FIG. 4). The photonic and active gain media may act synergistically. This combination should lead to a reduced lasing threshold for the NCs, making them more attractive for industrial applications.

Suitable photonic crystal structures can include three-dimensional opal templates. Opal samples can be prepared from a variety of particles diameters ranging from 220 nm to 600 nm via the vertical deposition technique. Both the volume fraction of particles in the precursor solution and the particle size dictate the number of resulting opal layers. After slow evaporation on a vibration isolation table, strong opalescence is visible in the samples. These opals are generally sintered at about 100° C. for about 2 hours to prevent them from falling apart during infiltration and then combined with SG/NC composites via controlled dipping and withdrawal. SG/NC composites are very attractive infiltration materials because of their large volume fraction of NCs (as high as 20%), stable photoluminescence (PL) quantum yields (QYs), and tunable index of refraction (up to 2.1). While such indices of refraction are not sufficient to open a complete photonic band gap, the resulting pseudogap still modifies the emission properties of the NCs.

The dipping process for infiltration of SG/NC composites into PCs allows variable filling fractions, which provide control over the position of the post-filling PC pseudogap. Upon infiltration with the SG/NC composite, the band position could be shifted reliably up to 10% depending on the filling factor (R_{fill} ranging from 0 to 1). Filling fractions are estimated by using pseudogap positions calculated from Bragg's Law before and after infiltration, given in Equation 1.

$$\frac{δ λ}{λ} = \sqrt{1 + {R}_{fill} {n}_{func}} - 1 , where {n}_{func} = \frac{{n}_{fill}^{2} - 1}{2.846 {n}_{sphere}^{2} + 1}$$

Here, λ is the initial band position (before filling), δλ is the change in the band position upon infiltration, nₛₚₕₑᵣₑ is the refractive index of the spheres, and n_{fill} is the refractive index of the infiltrating material. As the CdSe SG/NC composite used in this work is known to have an index or refraction of 2.10, complete filling produces a 21% shift in the band position. The SG/NC composite does not infiltrate into pores and cracks, leaving a seemingly uniform coating on the polystyrene surfaces. After infiltration with the CdSe NC/titania SG composite, the normal incidence opalescence changes from green to bright red, closely matching the color of the raw sol-gel by eye.

During infiltration, it is possible for void spaces to close off, limiting further infiltration. In processing of pure titania inverse opals, the infiltrated volume fraction can range from 12% to 20% of the total volume depending on the particle sizes used, where more complete infiltration is observed for larger particle sizes. The 50% void space filling (13% of the total volume) estimated for the present samples is at the lower end of that range in accordance with the small particle size used. Incomplete filling is not necessarily detrimental to the pseudogap, but can instead improve the gap strength. As shown by Busch and John (Phys. Rev. E, vol. 58, no. 3, 3896-3908 (1998)), slight sintering and incomplete filling of the void space increases the strength of the pseudogap for an inverted opal structure. The incomplete filling may result in a stronger pseudogap than would otherwise be obtainable if it were complete.

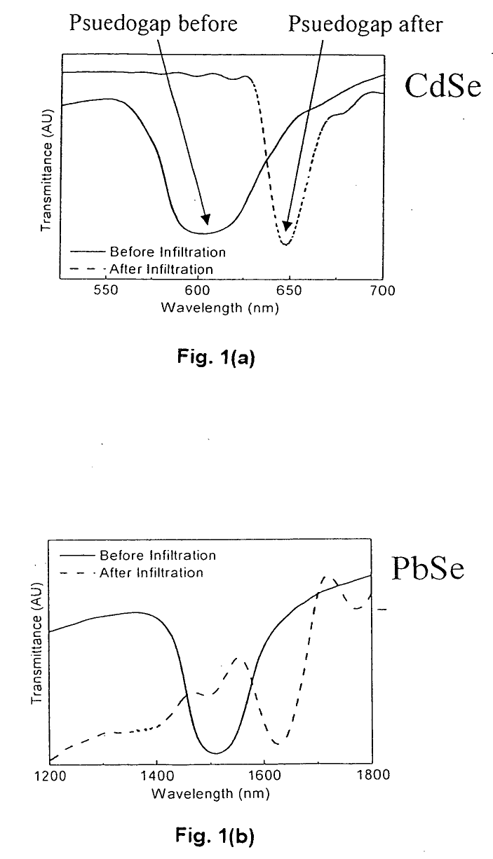

The process of the present invention can also be successfully applied to PbSe NCs whose emission is found in the near-IR spectral range. PbSe NCs are of interest as near infrared lasing materials because of the recent demonstration of ASE from 1425 to 1625 nm by Schaller et al., J. Phys. Chem. B, vol. 107, pp. 13765 (2003). In this case, the refractive index of the PbSe NC/titania SG composite was about 1.8-1.9. The pseudogap position before and after infiltration is shown in FIG. 1 for a representative sample of the PbSe NC-based materials. As different polystyrene particles were used with a refractive index near 1.59, a 7.7% shift upon infiltration corresponds to 50% filling (assuming a sol-gel refractive index of 1.9). An about 8% shift of the band gap position was observed upon infiltration.

To enable the possible enhancements of photonic structures on light emission, it is necessary to match the emission spectrum of the NCs with the photonic band gap. In particular, the emission maximum should be near a photonic gap or pseudogap in order to benefit from the enhanced density of state at these frequencies. The NC emission and the pseudogap position can be matched by varying the size of the NCs and polystyrene spheres, respectively. Coarse matching of the two positions can be obtained through NC size and composition variations, as well as by varying the opal lattice parameter. In the infiltration step, variation in the choice of dipping parameters allows for finer tuning to obtain the desire match.

For example, after dipping of the opaline film into the NC/sol-gel solution, withdrawal rates typically range from about 0.02 mm/minute to about 1 mm/minute. Slower withdrawal rates result in greater infiltration and can give the largest band gap shift, while slower withdrawal will generally result in lower infiltration and have a smaller shift.

For ASE studies, a 269-nm polystyrene sample infiltrated with the CdSe SG/NC composite was used. The sample exhibited a stop band shift of approximately 8-10% upon infiltration (approximately 50% filling). The loading of nanocrystals was estimated to be a maximum of 2.6% of the total sample volume. Samples were pumped using frequency-doubled pulses (3.1 eV photon energy) from a 100 femtosecond, regeneratively-amplified, Ti-Sapphire laser. The excitation spot on the sample was 450 microns. The sample emission was spectrally dispersed through a monochromator and detected by a liquid nitrogen cooled charge-coupled device.

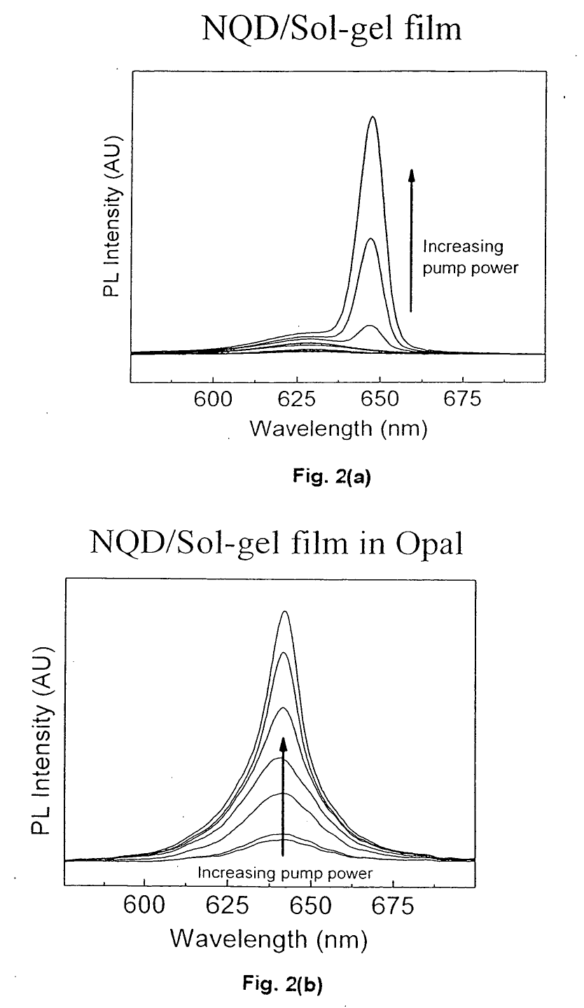

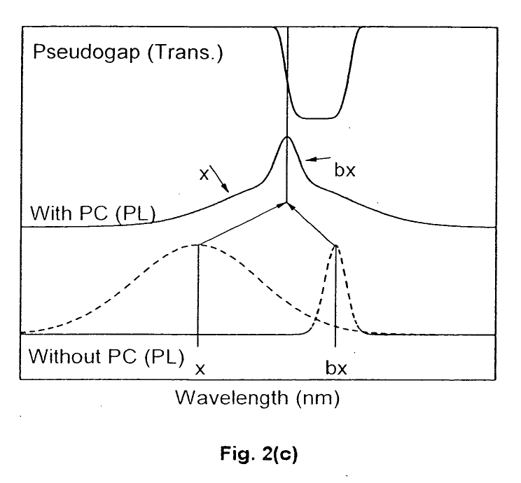

In one SG/NC sample, the PL was centered at 629-nm, while the ASE developed at 647-nm (see FIG. 2(a)). The red-shift of the ASE is due to light-reabsorption and the fact that spontaneous and stimulated emission are the result of excitons and biexcitons, respectively. The relative positions of these peaks were consistent with published results on SG/NC composites (see, e.g., Sundar et al., Adv. Mat., vol. 14, pp. 739 (2002)). When this SG/NC material was infiltrated into the 269 nm opal sample, spontaneous emission and ASE bands shifted to the same wavelength of 642 nm (see FIG. 2(b)). Since these peaks move in opposite directions, this result cannot be due, e.g., to increased re-absorption in the composite structure, but likely results from the effect of the photonic pseudogap. The increase in the photonic density of states at the edge of the pseudogap modifies the emission spectra of both excitons and biexciton, leading to the convergence of the spectral positions of the spontaneous and stimulated emission (see FIG. 2(c)).

The development of ASE in the photonic structure was evidenced by the spectral line narrowing and the fast superlinear growth of the emission intensity above the threshold fluence of about 3 mJ/cm. Interestingly, ASE was observed at relatively low NC filling factors (<3%), while in plain SG/NC films the development of ASE typically requires filling factors greater than 5%. This observation indicates that the optical gain in the PC structures is effectively enhanced because of the reduced group velocity at the edge of the photonic pseduogap. If the pseudogap and NC emission are not matched, the PL spectrum of the infiltrated SG/NC composite is essentially unchanged from that of an un-infiltrated SG/NC film. In unmatched infiltrated opals, ASE is not observed. These observations support the conclusion that the effects of the PC pseudogap on the NCs facilitates the development of ASE.

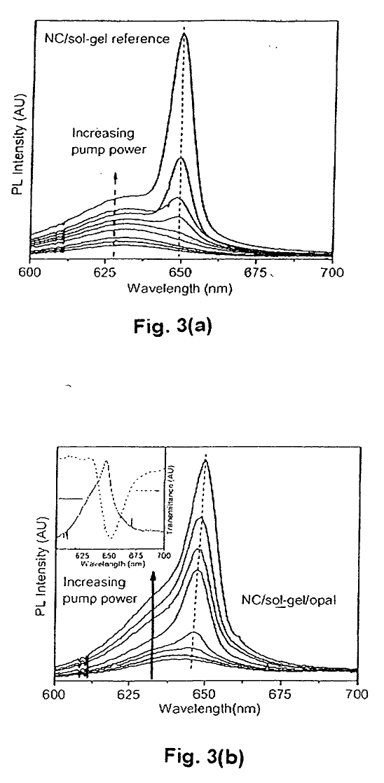

A greatly reduced ASE threshold has also been observed in similarly prepared samples. In FIG. 3, the PL spectrum for another NC/SG/PC sample and its reference are shown. In this case, a suppression of the ASE threshold was observed. A six nanometer shift of the ASE peak in the NC/SG/opal sample is observed, while the ASE position of the SG/NC film remains relatively unchanged. These observations again point to a strong interaction of the NC emission with the pseudogap. While some sample-to-sample variation was observed because of changes in the degree of overlap between the pseudogap and the NC emission and quality differences in the SG/NC and opal films, it was reproducibly observed that a strong suppression in the ASE threshold in fresh NC/SG/opal samples from batches with similar infiltration and NC emission.

Previously, the modal gain for the SG/NC with a 20% volume loading of NCs has been shown as 140 cm⁻¹ (see Petruska et al., Adv. Mat., vol. 15, pp. 610 (2003)). In the present material, the volume loading of NCs is a maximum of 2.6% as discussed previously. The average index of refraction of the NC/SG/PC film is estimated from the Bragg peak position to be 1.5 versus 2.1 for the SG/NC. Assuming a linear dependence of the gain with NC density and with the average index of refraction for a homogenized film, Equation 2 gives the estimated gain for the sol-gel in the absence of any photonic effect.

$${g}_{eff} = ( 130 {cm}^{- 1} ) \frac{{V}_{fract , SG \text{/} NC \text{/} PC}}{{V}_{fract , SG \text{/} NC}} \frac{{n}_{eff , SG \text{/} NC \text{/} PC}}{{n}_{eff , SG \text{/} NC}} = 12 {cm}^{- 1}$$

However, as ASE was observed with a 30-μm spot (FWHM), the gain is estimated to instead be over 300 cm⁻¹. This is a significant improvement over the estimated gain. It should be noted that despite the 130 cm⁻¹ modal gain for the SG/NC films, ASE was not observed before a stripe length of 0.053 cm. This is a stripe length 6.9 times larger than would be obtained by estimation form the modal gain, and about 18 times larger than the size observed in the NC/SG/PC film. The NC/SG/PC structure also has considerably more scattering that the SG/NC due to grain boundaries and cracks in the PC structure. The scattering should serve to reduce the observed gain, giving another indication that enhancements are even larger.

A low ASE threshold energy pulse was observed. As sample damage occurs above about 1 millijoule (mJ)/cm², the observation of ASE in the 30-μm spot was below this value. However, if this maximal energy spread over the 30-μm excitation spot is considered, there is approximately 20 nanojoule (nJ)/pulse when ASE was observed.

In the present invention, a strong effect was observed of the pseudogap on the spontaneous and stimulated emission in a synthetic opal infiltrated with a CdSe SG/NC composite. Despite the low loading of active material (<2.6 volume percent) and a sample thickness of only approximately 3 microns, ASE was clearly evident in the infiltrated samples. The ASE lines blue-shift away from that of the plain CdSe SG/NC films and are located at the blue pseudogap edges of the PCs. In several NC/SG/PC samples, a suppression of the ASE threshold was observed. This work points toward tunable NC/PC lasers that can benefit from the easy manipulation of NC emission properties and of PC stop band positions and the effective increase of the optical gain due to decreased group velocity at the edge of the PC gap.

The colloidal nanocrystals are generally members of a crystalline population having a narrow size distribution. The shape of the colloidal nanocrystals can be a sphere, a rod, a disk and the like. In one embodiment, the colloidal nanocrystals include a core of a binary semiconductor material, e.g., a core of the formula MX, where M can be cadmium, zinc, mercury, aluminum, lead, tin, gallium, indium, thallium, magnesium, calcium, strontium, barium, copper, and mixtures or alloys thereof and X is sulfur, selenium, tellurium, nitrogen, phosphorus, arsenic, antimony or mixtures thereof. In another embodiment, the colloidal nanocrystals include a core of a ternary semiconductor material, e.g., a core of the formula M₁M₂X, where M₁ and M₂ can be cadmium, zinc, mercury, aluminum, lead, tin, gallium, indium, thallium, magnesium, calcium, strontium, barium, copper, and mixtures or alloys thereof and X is sulfur, selenium, tellurium, nitrogen, phosphorus, arsenic, antimony or mixtures thereof. In another embodiment, the colloidal nanocrystals include a core of a quaternary semiconductor material, e.g., a core of the formula M₁M₂M₃X, where M₁, M₂ and M₃ can be cadmium, zinc, mercury, aluminum, lead, tin, gallium, indium, thallium, magnesium, calcium, strontium, barium, copper, and mixtures or alloys thereof and X is sulfur, selenium, tellurium, nitrogen, phosphorus, arsenic, antimony or mixtures thereof. In one embodiment, the colloidal nanocrystals are of silicon or germanium. Examples include cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), aluminum nitride (AlN), aluminum sulfide (AlS), aluminum phosphide (AlP), aluminum arsenide (AlAs), aluminum antimonide (AlSb), lead sulfide (PbS), lead selenide (PbSe), lead telluride (PbTe), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TlP), thallium antimonide (TlSb), zinc cadmium selenide (ZnCdSe), indium gallium nitride (InGaN), indium gallium arsenide (InGaAs), indium gallium phosphide (InGaP), aluminum indium nitride (AlInN), indium aluminum phosphide (InAlP), indium aluminum arsenide (InAlAs), aluminum gallium arsenide (AlGaAs), aluminum gallium phosphide (AlGaP), aluminum indium gallium arsenide (AlInGaAs), aluminum indium gallium nitride (AlInGaN) and the like, mixtures of such materials, or any other semiconductor or similar materials. In another embodiment, the colloidal nanocrystals include a core of a metallic material such as gold (Au), silver (Ag), cobalt (Co), iron (Fe), nickel (Ni), copper (Cu), manganese (Mn), alloys thereof and alloy combinations.

Additionally, the core of any semiconductor material or of any metallic material can have an overcoating on the surface of the core. The overcoating can also be a semiconductor material, such an overcoating having a composition different than the composition of the core. The overcoat on the surface of the colloidal nanocrystals can include materials selected from among Group II-VI compounds, Group II-V compounds, Group III-VI compounds, Group Ill-V compounds, Group IV-VI compounds, Group I-III-VI compounds, Group II-IV-V compounds, and Group II-IV-VI compounds. Examples include cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), aluminum nitride (AlN), aluminum phosphide (AlP), aluminum arsenide (AlAs), aluminum antimonide (AlSb), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TlP), thallium antimonide (TlSb), lead sulfide (PbS), lead selenide (PbSe), lead telluride (PbTe), zinc cadmium selenide (ZnCdSe), indium gallium nitride (InGaN), indium gallium arsenide (InGaAs), indium gallium phosphide (InGaP), aluminum indium nitride (AlInN), indium aluminum phosphide (InAlP), indium aluminum arsenide (InAlAs), aluminum gallium arsenide (AlGaAs), aluminum gallium phosphide (AlGaP), aluminum indium gallium arsenide (AlInGaAs), aluminum indium gallium nitride (AlInGaN) and the like, mixtures of such materials, or any other semiconductor or similar materials. The overcoating upon the core material can include a single shell or can include multiple shells for selective tuning of the properties. The multiple shells can be of differing materials.

In a process of the present invention, colloidal nanocrystals are mixed with a sol-gel precursor material and the resultant solution can be used to form a solid composite. For example, the solution can be deposited onto a suitable substrate to yield homogeneous, solid composites from the solution of colloidal nanocrystals and sol-gel precursor. By homogeneous, it is meant that the colloidal nanocrystals are uniformly dispersed in the resultant product. In some instances, non-uniform dispersal of the colloidal nanocrystals is acceptable. In some embodiments of the invention, the solid composites can be transparent or optically clear. This first process of the present invention is a simple straight-forward process for preparing such solid composites.

Sol-gel processes generally refer to the preparation of a ceramic material by preparation of a sol, gelation of the sol and removal of the solvent. Sol-gel processes are advantageous because they are relatively low-cost procedures and are capable of coating long length conductors or irregularly shaped substrates. In forming the sol-gel based solution used in the processes of the present invention, suitable sol-gel precursor materials are mixed with the other components.

Sol-gel processes can be carried out as described by Brinker et al, “Sol-Gel Science, The Physics and Chemistry of Sol-Gel Processing”, Academic Press, 1990. Among suitable sol-gel precursor materials are included metal alkoxide compounds, metal halide compounds, metal hydroxide compounds, combinations thereof and the like where the metal is a cation from the group of silicon, titanium, zirconium, and aluminum. Other metal cations such as vanadium, iron, chromium, tin, tantalum and cerium may be used as well. Sol solutions can be spin-cast, dip-coated, or sprayed onto substrates in air. Sol solutions can also be cast into desired shapes by filling molds or cavities as well. Among the suitable metal alkoxide compounds can be included titanium tetrabutoxide (titanium(IV)butoxide), titanium tetraethoxide, titanium tetraisopropoxide, zirconium tetraisopropoxide, tetraethoxysilane (TEOS). Among suitable halide compounds can be included titanium tetrachloride, silicon tetrachloride, aluminum trichloride and the like.

For the processes of the present invention, the colloidal nanocrystals can include all types of nanocrystals capped with hydrophobic ligands, including, e.g., semiconductor NQDs such as cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), aluminum nitride (AlN), aluminum phosphide (AlP), aluminum arsenide (AlAs), aluminum antimonide (AlSb), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TlP), thallium antimonide (TlSb), lead sulfide (PbS), lead selenide (PbSe), lead telluride (PbTe), and mixtures of such materials. The colloidal nanocrystals can also be metal nanoparticles such as gold (Au), silver (Ag), cobalt (Co), iron (Fe), nickel (Ni), copper (Cu), manganese (Mn), alloys thereof and alloy combinations thereof.

The present invention is more particularly described in the following example that is intended as illustrative only, since numerous modifications and variations will be apparent to those skilled in the art.

CdSe colloidal nanocrystals were synthesized as previously described by Murray et al., J. Am. Chem. Soc., v. 113, 8706 (1993), and by Qu et al., J. Am. Chem. Soc., v. 124, 2049 (2002).

### EXAMPLE 1

Monodisperse polystyrene particles were obtained form Duke Scientific (220, 240, and 269 nm) and IDC Latex (310, 404, and 600 nm). Opals were produced via vertical deposition onto cut microscope slides (1 mm thick) from a solution of 0.25 volume percent particles for the 220, 240 and 269 nm samples and a 1 to 5 volume percent solution for all larger particle samples. During the vertical deposition process, a vibration isolation table was used to prevent disruption. After the samples were dry, they were sintered at 100° C. for 2 hours to increase the stability of the samples during NC/sol-gel infiltration. NC/sol-gel solutions were prepared as described by Sundar et al., Adv. Mat., vol. 14, pp. 739 (2002) and Petruska et al., Adv. Mat., vol. 15, pp. 610 (2003) for CdSe and by Schaller et al., J. Phys. Chem. B, vol. 107, pp. 13765 (2003) for PbSe, such descriptions incorporated herein by reference. It was necessary to dilute solutions to 4% THF with 1-propanol to prevent degradation of the polystyrene films. Infiltration of the opaline film was achieved via controlled dipping of the opaline film into a solution of the NC/sol-gel composite. A servo controlled DC motor on a KSV Langmuir-Blodgett trough was used to regulate dipping and withdrawal rates of the opaline film into the NC/sol-gel solution. Samples were rapidly submersed and then withdrawn at rates ranging from 0.02 to 1 mm/min. The photonic pseudogap position was measured before and after infiltration. For the 269 nm polystyrene particles obtained from Duke Scientific, the position before infiltration was 601 nm±3 nm (averaged over 23 samples). As the sizes of these spheres was verified to be 269 nm, the index of refraction of the spheres must be 1.48 instead of the 1.59 typical of dense polystyrene to correspond favorably with Bragg's Law. Other works have noticed this discrepancy between the expected Bragg peak and the measured for Duke Scientific samples, but they suggest this result may be due to shrinkage of the latex spheres upon drying. However, this discrepancy between the sphere size and Bragg's Law was not observed in opals composed of latex spheres obtained from IDC Latex, Inc.

Although the present invention has been described with reference to specific details, it is not intended that such details should be regarded as limitations upon the scope of the invention, except as and to the extent that they are included in the accompanying claims.

What is claimed is:

1. A composite photonic crystal material comprising:
a photonic crystal structure having voids throughout, said photonic crystal structure including a colloidal nanocrystal-doped composite infiltrated within said voids, said colloidal nanocrystal-doped composite including a sol-gel or polymeric host/matrix material.

2. The composite photonic crystal material of claim 1 wherein said photonic crystal structure is selected from the group consisting of one-dimensional structures, two-dimensional structures and three-dimensional structures.

3. The composite photonic crystal material of claim 1 wherein said photonic crystal structure having voids throughout is selected from the group consisting of three-dimensional opal templates, three-dimensional inverse opal templates and three-dimensional holographically-formed structures.

4. The composite photonic crystal material of claim 1 wherein the sol-gel is selected from the group consisting of titania, silica, ceria, alumina, zirconia, germania, baria, lead oxide and alloys hereof.

5. The composite photonic crystal material of claim 1 wherein said sol-gel is formed from a sol-gel precursor material selected from the group consisting of metal alkoxide compounds, metal halide compounds, and metal hydroxide compounds where the metal is selected from the group consisting of silicon, titanium, zirconium, aluminum, vanadium, iron, tin, tantalum, cerium, and chromium.

6. The composite photonic crystal material of claim 1 wherein said nanocrystals are selected from the group consisting of M₁X, M₁M₂X, and M₁M₂M₃X, where M₁, M₂, and M₃ are each selected from the group consisting of Zn, Cd, Hg, Al, Ga, In, Tl, Pb, Sn, Mg, Ca, Sr, Ba, mixtures and alloys thereof and X is selected from the group consisting of S, Se, Te, As, Sb, N, P and mixtures thereof, Si, Ge, Au, Ag, Co, Fe, Ni, Cu, Mn and alloys of Au, Ag, Co, Fe, Ni, Cu, Mn or alloy combinations thereof.

7. The composite photonic crystal material of claim 1 characterized by a reduction in amplified spontaneous emission threshold and enhancement of optical gain in comparison to a reference film of said nanocrystal-doped sol-gel composition.

8. The composite photonic crystal material of claim 1 wherein said colloidal nanocrystal-doped composite includes a polymer or a sol-gel.

9. The composite photonic crystal material of claim 1 wherein said photonic crystal structure is of a material selected from the group consisting of silica, alumina, titania and polystyrene.

10. A process of preparing a composite photonic crystal material comprising
filling a photonic crystal structure having voids throughout with a colloidal nanocrystal-doped composite precursor mixture for a period of time sufficient to form said photonic crystal material.

11. A process of forming a one-dimensional composite photonic crystal material comprising forming alternating layers of (a) a photonic medium and (b) a colloidal nanocrystal-doped polymeric or sol-gel material upon a suitable substrate.

12. A one-dimensional composite photonic crystal material comprising:
a substrate; and,
alternating layers of (a) a photonic medium and (b) a colloidal nanocrystal-doped polymeric or sol-gel material thereon said substrate.

13. The one-dimensional composite photonic crystal material of claim 12 wherein said photonic medium is of a material selected from the group consisting of titania, alumina, silica, and polystyrene.

14. The one-dimensional composite photonic crystal material of claim 12 wherein said nanocrystals are selected from the group consisting of M₁X, M₁M₂X, and M₁M₂M₃X, where M₁, M₂, and M₃ are each selected from the group consisting of Zn, Cd, Hg, Al, Ga, In, Tl, Pb, Sn, Mg, Ca, Sr, Ba, mixtures and alloys thereof and X is selected from the group consisting of S, Se, Te, As, Sb, N, P and mixtures thereof, Si, Ge, Au, Ag, Co, Fe, Ni, Cu, Mn and alloys of Au, Ag, Co, Fe, Ni, Cu, Mn or alloy combinations thereof.
